(19) United States
(12) Patent Application Publication
(10) Pub. No.: US 2021/0090964 A1
(43) Pub. Date: Mar. 25, 2021

(54) SEMICONDUCTOR DEVICE AND MANUFACTURING METHOD OF IMAGING DEVICE AND SEMICONDUCTOR DEVICE

(71) Applicant: SONY SEMICONDUCTOR SOLUTIONS CORPORATION, KANAGAWA (JP)

(72) Inventor: NOBUTAKA ATAGO, OITA (JP)

(21) Appl. No.: 16/961,472

(22) PCT Filed: Nov. 27, 2018
(86) PCT No.: PCT/JP2018/043650

§ 371 Date: Jul. 10, 2020

(30) Foreign Application Priority Data
Jan. 26, 2018 (JP) 2018-011331

(51) Int. Cl. H01L 23/08; H01L 27/146; H04N 5/335; H01L 23/00

(52) U.S. Cl. CPC H01L 23/08; H01L 24/32; H04N 5/335; H01L 27/146

(57) ABSTRACT

To prevent damage of a semiconductor package by deformation of members forming the semiconductor package in accordance with a change in temperature. A semiconductor device is provided with a frame, a semiconductor chip, and a lid. The frame includes a bottom and a wall arranged so as to be adjacent to the bottom and formed into an annular shape, the wall provided with a protrusion continuous in a circumferential direction of the annular shape on an upper surface. The semiconductor chip is placed on the bottom surrounded by the wall. The lid is adhered to the frame at an upper surface.

### TECHNICAL FIELD

The present disclosure relates to a semiconductor device and a manufacturing method of an imaging device and a semiconductor device. Specifically, this relates to a semiconductor device formed in a hollow package and a manufacturing method of an imaging device and the semiconductor device.

### BACKGROUND ART

Conventionally, a semiconductor device is enclosed in a package to prevent moisture and the like. In an imaging device which images a subject among such semiconductor devices, a lid of glass and the like is adhered by an adhesive to a frame of a ceramic and the like in which a concave portion for arranging an imaging element chip is generated to form a package. As such imaging device, for example, a solid-state imaging element is used in which an adhesive is arranged between a lid-shaped cap glass and an annular cap glass adhering portion surrounding the concave portion of a ceramic package, the adhesive is melted in a high-temperature state, and then cooled to be cured, thereby performing adhesion (for example, refer to Patent Document 1).

In such solid-state imaging element, a case is supposed where the adhesive softened due to the high temperature state at the time of adhesion enters the package from the cap glass adhering portion and moves to the vicinity of the imaging element. In contrast, in the above-described solid-state imaging element, a protrusion is formed on an innermost periphery of the annular cap glass adhering portion, and the adhesive is arranged on an outermost periphery. The protrusion arranged on the innermost periphery prevents the softened adhesive from entering the package.

### CITATION LIST

### Patent Document

Patent Document 1: Japanese Patent Application Laid-Open No. H04-337668

### SUMMARY OF THE INVENTION

### Problems to be Solved by the Invention

In the above-described conventional technology, a gas such as air enclosed in the package expands due to heating at the time of adhesion, and the frame and the cap glass swell. Furthermore, the package bends in accordance with a change in temperature during use. There is a problem that a stress is concentrated on the adhesive due to deformation of members forming such package to cause a crack and the like, and the semiconductor package is damaged.

The present technology is achieved in view of the above-described problem, and an object thereof is to prevent damage of a semiconductor package by deformation of a member forming the semiconductor package in accordance with a change in temperature.

### Solutions to Problems

The present technology is achieved for solving the above-described problem, and a first aspect thereof is a semiconductor device provided with a frame including a bottom and a wall arranged so as to be adjacent to the bottom and formed into an annular shape, the wall provided with a protrusion continuous in a circumferential direction of the annular shape on an upper surface, a semiconductor chip placed on the bottom surrounded by the wall, and a lid adhered to the frame at the upper surface. This brings about an effect that a distance to the lid in an annular area other than an area where the protrusion is arranged on the upper surface of the frame increases. When the adhesive is arranged, it is supposed that the adhesive is thickened in the area other than the area where the protrusion is arranged.

Furthermore, in this first aspect, the frame may also be provided with the protrusion formed into a downward slope from an apex. This brings about an effect that the distance between the upper surface of the frame and the lid gradually changes along the slope.

Furthermore, in the first aspect, the frame may be provided with the protrusion including the apex formed on an outer periphery of the upper surface. This brings about an effect that the distance between the upper surface of the frame and the lid gradually changes from the outer periphery of the upper surface.

Furthermore, in the first aspect, the frame may be provided with the protrusion including the apex formed on an inner periphery of the upper surface. This brings about an effect that the distance between the upper surface of the frame and the lid gradually changes from the inner periphery of the upper surface.

Furthermore, in the first aspect, the frame may be provided with the protrusion including the apex formed in a central portion of the upper surface. This brings about an effect that the distance between the upper surface of the frame and the lid gradually changes from the central portion toward the outer periphery and the inner periphery of the upper surface.

Furthermore, in the first aspect, the frame may be provided with the protrusion including a step formed on the upper surface. This brings about an effect that the distance between the upper surface of the frame and the lid changes along the step.

Furthermore, in the first aspect, an adhesive arranged between the upper surface and the lid to be cured while being pressurized may be further provided. This brings about an effect that the frame and the lid are adhered while being pressurized.

Furthermore, a second aspect of the present technology is an imaging device provided with a frame including a bottom and a wall arranged so as to be adjacent to the bottom and formed into an annular shape, the wall provided with a protrusion continuous in a circumferential direction of the annular shape on an upper surface,

an imaging element placed on the bottom surrounded by the wall, and a lid adhered to the frame at the upper surface and transmits light incident on the imaging element. This brings about an effect that a distance to the lid in an annular area other than an area where the protrusion is arranged on the upper surface of the frame increases. When the adhesive is arranged, it is supposed that the adhesive is thickened in the area other than the area where the protrusion is arranged.

Furthermore, a third aspect of the present technology is a manufacturing method of a semiconductor device provided with an adhesive arranging step of arranging an adhesive by applying the adhesive to an upper surface of a frame including a bottom and a wall arranged so as to be adjacent to the bottom and formed into an annular shape, the wall provided with a protrusion continuous in a circumferential direction of the annular shape on an upper surface, a lid placing step of placing a lid on the upper surface of the frame on which the adhesive is arranged, and an adhering step of adhering the frame and the lid by curing while pressurizing the arranged adhesive. This brings about an effect that a distance to the lid in an annular area other than an area where the protrusion is arranged on the upper surface of the frame increases. When the adhesive is arranged, it is supposed that the adhesive is thickened in the area other than the area where the protrusion is arranged.

### Effects of the Invention

According to the present technology, there is an excellent effect of preventing damage of a semiconductor package by deformation of a member forming the semiconductor package in accordance with a change in temperature.

### BRIEF DESCRIPTION OF DRAWINGS

FIG. 1 is a view illustrating a configuration example of an imaging device according to an embodiment of the present technology.

FIG. 2 is a cross-sectional view illustrating a configuration example of an imaging device according to a first embodiment of the present technology.

FIG. 3 is a view illustrating a stress applied to an adhesive according to the first embodiment of the present technology.

FIG. 4 is a view illustrating an example of a manufacturing method of the imaging device according to the first embodiment of the present technology.

FIG. 5 is a cross-sectional view illustrating a configuration example of an imaging element according to a variation of the first embodiment of the present technology.

FIG. 6 is a cross-sectional view illustrating a configuration example of an imaging device according to a second embodiment of the present technology.

FIG. 7 is a cross-sectional view illustrating a configuration example of an imaging device according to a third embodiment of the present technology.

FIG. 8 is a cross-sectional view illustrating a configuration example of an imaging device according to a fourth embodiment of the present technology.

FIG. 9 is a block diagram illustrating a schematic configuration example of a camera which is an example of an imaging device to which the present technology may be applied.

### MODE FOR CARRYING OUT THE INVENTION

Next, modes for carrying out the present technology (hereinafter, referred to as embodiments) are described with reference to the drawings. In the following drawings, the same or similar parts are assigned with the same or similar reference signs. However, the drawings are schematic, and dimensional ratios and the like of the respective parts do not necessarily match actual ones. Furthermore, it is needless to say that dimensional relationships and ratios are partly different between the drawings. Furthermore, the embodiments are described in the following order.

1. First Embodiment

2. Second Embodiment

3. Third Embodiment

4. Fourth Embodiment

5. Application Example to Camera

### 1. FIRST EMBODIMENT

[Configuration of Imaging Device]

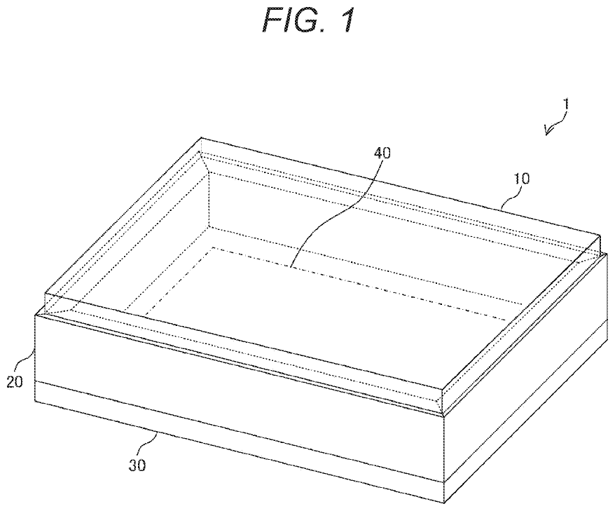

FIG. 1 is a view illustrating a configuration example of an imaging device according to an embodiment of the present technology. An imaging device 1 in this drawing is provided with a lid 10, a wall 20, a bottom 30, and an imaging element 40. A semiconductor device according to the present technology is described by taking the imaging device 1 as an example. Note that, the imaging device 1 is an example of a semiconductor device recited in claims.

The imaging element 40 is a semiconductor chip which images incident light. The imaging element 40 converts light from a subject incident via the lid 10 to be described later into an image signal and outputs the same. The imaging element 40 is formed by arranging pixels each including a photoelectric conversion unit which performs photoelectric conversion to generate an electric signal according to the incident light in a two-dimensional lattice manner.

The bottom 30 is a substrate on which the imaging element 40 is mounted. The bottom 30 includes a wiring layer which transmits the electric signal and an insulating layer which insulates the wiring layer. Furthermore, the bottom 30 on which the imaging element 40 is placed is electrically connected to the imaging element 40, and transmits the electric signal between the imaging element 40 and a circuit outside the imaging device 1. The wiring layer may be formed by using metal such as copper (Cu) or tungsten (W), for example. Furthermore, the insulating layer may be formed by using a ceramic or a resin, for example. The wiring layers and the insulating layers are alternately stacked to form multilayer wiring. The bottom 30 illustrated in the drawing is an example in which a surface on which the imaging element 40 is placed is formed into a rectangular shape.

The wall 20 is an annular wall which surrounds the imaging element 40 and is arranged so as to be adjacent to the bottom 30. The wall 20 is adhered to the lid 10 to be described later at an upper surface. Here, the upper surface is a surface opposed to a bottom surface which is a surface adjacent to the bottom 30. The upper surface is formed into an annular shape, and a protrusion continuous in a circumferential direction of the annular shape is arranged on the annular upper surface. On the wall 20 in the drawing, the protrusion formed into a downward slope from an apex arranged on an outermost periphery of the upper surface is arranged. A configuration of the protrusion is described later in detail. The wall 20 may be formed by using a ceramic, a resin, metal and the like, for example. The wall 20 in the drawing is formed to have a rectangular outer shape according to a shape of the surface of the bottom 30. Note that, the bottom 30 and the wall 20 form a frame. Furthermore, the frame and the lid 10 form a semiconductor package.

The lid 10 is a lid which covers an upper portion of the imaging element 40. The lid 10 is adhered to the upper surface of the wall 20 with an adhesive to form the semiconductor package. Furthermore, the lid 10 is formed by using a translucent member such as glass.

Note that, the configuration of the imaging device 1 is not limited to this example. For example, it is also possible to use a frame in which the wall 20 is integral with the bottom 30.

[Configuration of Cross-section of Imaging Device]

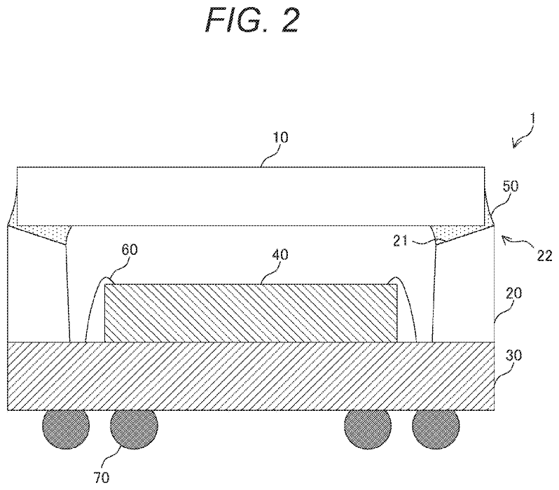

FIG. 2 is a cross-sectional view illustrating a configuration example of an imaging device according to a first embodiment of the present technology. This is a schematic cross-sectional view illustrating a configuration example of the imaging device 1. As illustrated in the drawing, an imaging element 40 is placed on a bottom 30 and electrically connected to a conductor layer of the bottom 30 by a bonding wire 60. Specifically, the bonding wire 60 is connected by wire bonding between a pad (not illustrated) arranged on a surface of the imaging element 40 and a pad (not illustrated) arranged on the surface of the bottom 30. Note that, the imaging element 40 is joined to the bottom 30 with an adhesive not illustrated.

A spherical solder 70 is arranged on a rear surface of the bottom 30. The solder 70 is joined to the wiring layer of the bottom 30. Furthermore, when the imaging device 1 is mounted on an external circuit board, the solder 70 is soldered to a pad formed on the external circuit board. In this manner, an electric signal is transmitted between the bottom 30 and the circuit board via the solder 70.

A lid 10 is adhered to an upper surface 21 of a wall 20 with an adhesive 50. A protrusion 22 is arranged on the upper surface 21 in the drawing. The protrusion 22 is formed into a downward slope from an apex. Furthermore, the protrusion 22 is arranged on an entire circumference of an outermost periphery of an annular upper surface. That is, the upper surface 21 in the drawing is formed into a slope downward from the outermost periphery toward an innermost periphery. The lid 10 is formed into a shape smaller than an outer periphery of the wall 20, and an end thereof is adhered to a position adjacent to the middle of the slope of the above-described protrusion 22.

As the adhesive 50, for example, a thermosetting resin or a photocurable resin may be used. As illustrated in the drawing, the adhesive 50 is arranged between the lid 10 and the upper surface 21 of the wall 20 to adhere the lid 10 to the wall 20. As described above, since the slope by the protrusion 22 is formed on the upper surface 21, a thickness of the adhesive 50 increases from the outer periphery toward the inner periphery of the upper surface 21. By arranging the protrusion 22 on the upper surface 21, the adhesive 50 may be made thick in a partial area between the lid 10 and the wall 20.

In a case where the thermosetting resin is used as the adhesive 50, it is necessary to apply the adhesive 50 before curing between the upper surface 21 of the wall 20 and the lid 10 and then heat the same to cure. Furthermore, in a case where the photocurable resin is used as the adhesive 50 also, heating is performed after applying ultraviolet rays and the like to cure. This is for completely curing the adhesive 50. At the time of this heating, the lid 10 and the like deforms and a stress is applied to the adhesive 50, so that distortion occurs in the adhesive 50. In a case where the stress of the adhesive 50 is large, the distortion also increases, and there is damage such as a crack of the adhesive 50.

Furthermore, a semiconductor element for use on vehicle is used in a relatively wide temperature range. In a case where the imaging device 1 is used for use on vehicle, a large stress is repeatedly applied to the semiconductor package. AEC-Q100 is applied as a reliability test to the semiconductor element supposed to be used in such a severe environment. With this AEC-Q100, for example, a 1000-cycle test is carried out at −55 to 125° C. as a temperature cycle test. When the temperature changes from low temperature to high temperature, the lid 10 and the bottom 30 expand and contract. At that time, in a case where thermal expansion coefficients of the lid 10 and the like are different, an entire semiconductor package bends.

For example, in a case where glass as an inorganic material is used as the lid 10 and an organic material such as a resin is used as the bottom 30, it is supposed that the imaging device 1 bends into a downward convex shape as the temperature rises. This is because an amount of expansion of the bottom 30 is larger than that of the lid 10. In contrast, it is supposed that the imaging device 1 bends into an upward convex shape as the temperature falls. When the imaging device 1 deforms in this manner, the stress concentrates on a periphery of the imaging device 1 and a strong stress is applied to the adhesive 50.

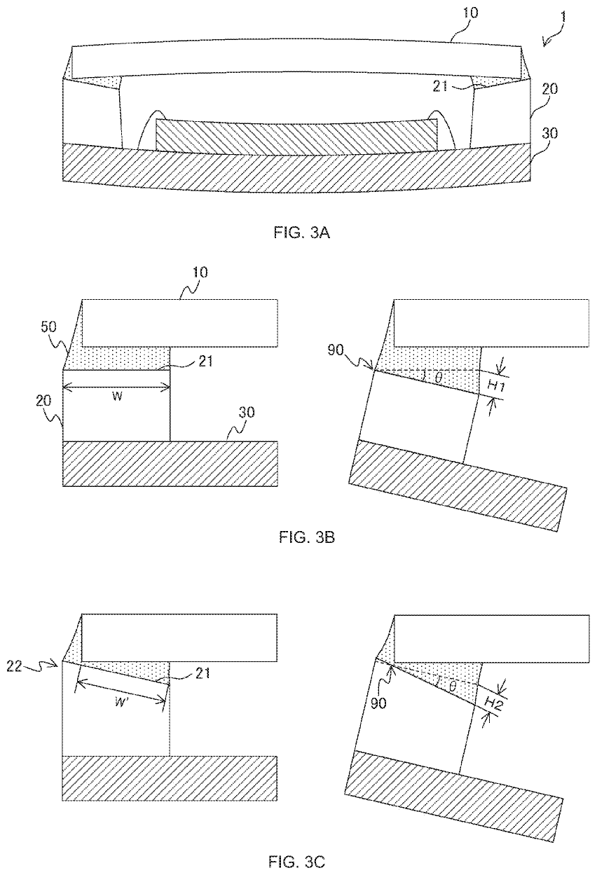

In this manner, the stress is concentrated on the adhesive 50 at the time of manufacture and during use of the imaging device 1. However, as illustrated in the drawing, by making the adhesive 50 thick, it is possible to disperse the stress applied to the adhesive 50 at the time of manufacture or during use and prevent damage of the adhesive 50. This state is described with reference to FIG. 3.

[Relief of Stress]

FIG. 3 is a view illustrating the stress applied to the adhesive according to the first embodiment of the present technology. a in the drawing is a cross-sectional view illustrating a state of the imaging device 1 heated for curing the adhesive 50. Note that, the solder 70 is not illustrated in the drawing.

When the adhesive 50 is cured by heating, pressure is applied to compress the lid 10 toward the wall 20 in order to prevent positional displacement of the lid 10 and the wall 20. This may be performed, for example, by making an atmosphere of the imaging device 1 a positive pressure atmosphere with a pressure container. However, a gas such as air enclosed inside the semiconductor package has no escape area, so that this expands in the semiconductor package as the temperature rises. Therefore, the lid 10 and the bottom 30 deform into a shape swelling outward, and the stress is applied in a direction of cleaving the adhesive 50 with an end of the lid 10 as a fulcrum.

b of the drawing is a view illustrating an example of a case where the protrusion 22 is not arranged on the upper surface 21 as a comparative example. Left and right views in b of the drawing are views illustrating states of the adhesive 50 before and during heating, respectively. In the left view in b of the drawing, W represents a width of the upper surface 21. When the imaging device 1 is heated, as illustrated in the right view in b of the drawing, the lid 10 and the wall 20 deform in a direction to open upward and downward in the drawing with an end of the wall 20 as a fulcrum (fulcrum 90). Supposing a case where the adhesive 50 deforms by an angle θ around the fulcrum 90, distortion H1 in the inner periphery of the adhesive 50 is expressed as

H1=W×tanθ.

In a case where W and θ are 0.8 mm and 20°, respectively, H1 is 0.29 mm.

c of the drawing is a view illustrating an example of a case where the protrusion 22 is arranged on the upper surface 21. As in b of the drawing, left and right views in c of the drawing are views illustrating states of the adhesive 50 before and during heating, respectively. In the left view in c of the drawing, the end of the lid 10 is adjacent to the wall 20 in the middle of the slope of the protrusion 22 of the upper surface 21. Therefore, the adjacent position becomes the fulcrum 90. When a width from an inner peripheral end of the upper surface 21 to the adjacent position of the end of the lid 10 is set to W′, W′ is smaller than W. In this case, distortion H2 in the inner periphery of the adhesive is expressed as

H2=W′×tanθ.

In a case where W′ is, for example, 0.65 mm, H2 is 0.24 mm, and the distortion decreases by 19% as compared with b of the drawing. In this manner, by arranging the protrusion 22 on the upper surface 21, the fulcrum when the stress is applied to the adhesive 50 moves, so that the distortion of the adhesive 50 may be decreased.

Furthermore, the adhesive 50 is thicker in the inner periphery than in the outer periphery due to the slope of the protrusion 22. A larger stress is applied to the inner periphery than in the outer periphery of the adhesive 50 due to the deformation of the lid and the like at the time heating, but the inner periphery in which the adhesive 50 is thicker may absorb the large stress. In this manner, even in a case where the fulcrum 90 does not move, the stress is relieved by arranging the protrusion 22 and the damage of the adhesive 50 may be prevented.

Note that, the shape of the protrusion 22 is not limited to this example. For example, the protrusion 22 may be arranged on a side portion except the vicinity of a corner of the wall 20. Furthermore, for example, the protrusion 22 may be arranged on the upper surface 21 on a long side of the rectangular wall and the protrusion on the upper surface 21 on a short side may be omitted.

[Manufacturing Method of Imaging Device]

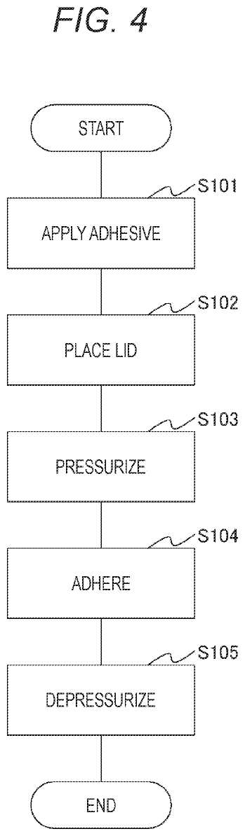

FIG. 4 is a view illustrating an example of a manufacturing method of the imaging device according to the first embodiment of the present technology. This is a view illustrating a manufacturing step of the imaging device 1. First, the imaging element 40 is mounted on the bottom 30, and the adhesive 50 is applied to the upper surface 21 of the wall 20 to arrange. The adhesive 50 may be applied by, for example, a dispenser (step S101). Next, the lid 10 is placed on the upper surface 21 after positioning (step S102). Next, the imaging device 1 is pressurized by the pressure container and the like. This may be performed, for example, by gradually increasing the pressure from atmospheric pressure to 0.042 MPa (step S103). Next, adhesion is performed. This may be performed by heating the imaging device 1 in a pressurized state to cure the adhesive 50. The heating may be performed, for example, by gradually raising the temperature from room temperature to 130° C. (step S104). After the adhesive 50 is cured, the heating is stopped.

Next, the pressure is decreased to the atmospheric pressure (step S105). Next, the imaging device 1 is cooled to temperature near room temperature, and the solder 70 is arranged on the bottom 30. The imaging device 1 may be manufactured by steps described above. Note that, the manufacturing method of the imaging device 1 is not limited to this example. For example, the imaging device 1 may be heated at the same time as the imaging device 1 is pressurized at step 5103. Furthermore, it is also possible to adopt a step of stopping heating the imaging device 1 after the pressure is decreased to the atmospheric pressure.

Note that, step S101 is an example of an adhesive arranging step recited in claims. Step S102 is an example of a lid placing step recited in claims. Step S104 is an example of an adhering step recited in claims.

[Variation]

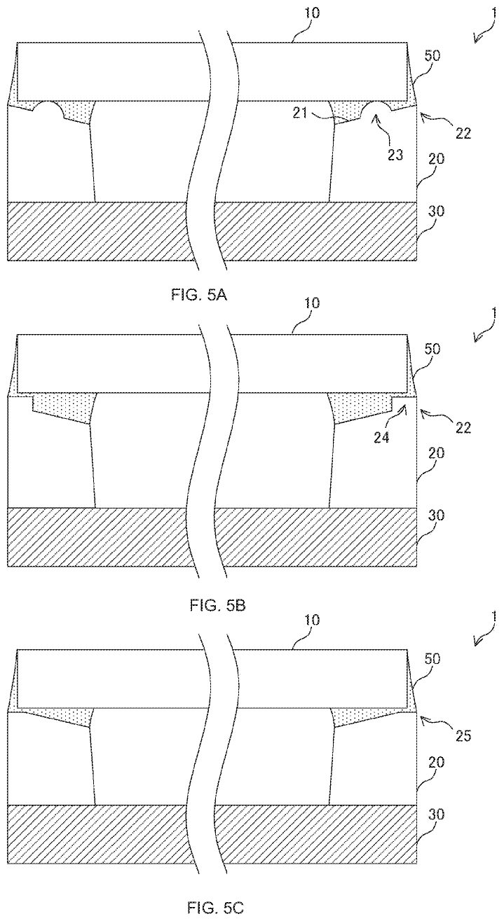

FIG. 5 is a cross-sectional view illustrating a configuration example of an imaging element according to a variation of the first embodiment of the present technology. In the drawing, an imaging element 40 and a solder 70 are not illustrated. a of the drawing illustrates an example in which a bump 23 is arranged in the middle of a slope of a protrusion 22. The bump 23 may facilitate positioning when adhering a lid 10 to a wall 20. The bump 23 may be arranged in any position on an upper surface 21. Furthermore, it is also possible to arrange a protrusion continuous in a circumferential direction of the upper surface 21 in place of the bump 23.

The bump 23 may be formed by using a spacer, for example. At that time, it is preferable to use the spacer formed by using the same material as that of an adhesive 50. This is because stress concentration on the adhesive 50 in the vicinity of the bump 23 may be relieved.

b of the drawing illustrates an example in which a protrusion 24 continuous in the circumferential direction of the upper surface 21 is arranged on an apex of the protrusion 22. Furthermore, c of the drawing illustrates an example of a case where a protrusion 25 in a shape obtained by chamfering an apex is arranged in place of the protrusion 22. In these cases also, it becomes possible to easily perform positioning when adhering the lid 10 to the wall 20.

As described above, in the imaging device 1 according to the first embodiment of the present technology, the adhesive 50 may be partially made thicker by arranging the protrusion 22 on the upper surface 21 of the wall 20. Stress concentration based on a change in temperature at the time of manufacture and during use of the imaging device 1 is relieved, and the damage of the imaging device 1 may be prevented.

### 2. SECOND EMBODIMENT

The imaging device 1 according to the first embodiment described above uses the protrusion 22 with the apex formed on the outermost periphery of the annular upper surface 21. In contrast, an imaging device 1 according to a second embodiment of the present technology is different from that of the first embodiment described above in using a protrusion with an apex formed on an innermost periphery of an annular upper surface 21.

[Configuration of Cross-section of Imaging Device]

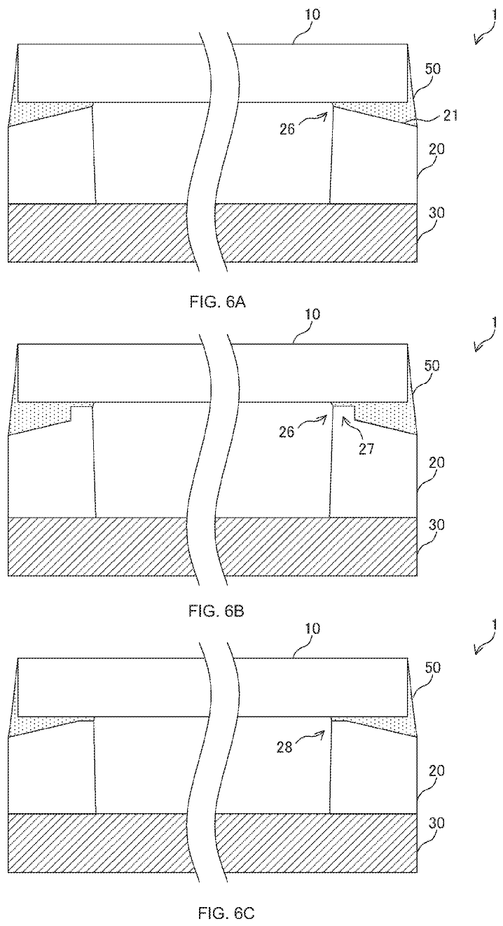

FIG. 6 is a cross-sectional view illustrating a configuration example of the imaging device according to the second embodiment of the present technology. This is a schematic cross-sectional view illustrating a configuration example of the imaging device 1. The imaging device 1 in the drawing is different from the imaging device 1 illustrated in FIG. 2 in that a protrusion 26 is provided in place of the protrusion 22.

In a of the drawing, the protrusion 26 is formed into a slope downward from the apex arranged on the innermost periphery of the annular upper surface 21. Just as the protrusion 22, the protrusion 26 may be arranged on an entire circumference of the annular upper surface 21. Since the apex of the protrusion 26 is arranged on the innermost periphery of the upper surface 21, a thickness of an adhesive 50 increases from an inner periphery toward an outer periphery of the upper surface 21.

As described above, during use of the imaging device 1, a case where a lid 10 bends in a direction opposite to that in FIG. 3 is also supposed. In such a case, a stress in a tensile direction is applied to the outer periphery of the adhesive 50. However, the apex of the protrusion 26 serves as a fulcrum and a width of a distortion area of the adhesive 50 is shortened from W to W′ and the distortion is decreased with as in c of FIG. 3.

b of the drawing illustrates an example in which a protrusion 27 continuous in a circumferential direction of the upper surface 21 is arranged on the apex of the protrusion 26. Furthermore, c of the drawing illustrates an example of a case where a protrusion 28 in a shape obtained by chamfering an apex is arranged in place of the protrusion 26.

Since the configuration of the imaging device 1 other than this is similar to the configuration of the imaging device 1 described in the first embodiment of the present technology, the description thereof is omitted.

As described above, in the imaging device 1 according to the second embodiment of the present technology, the protrusion 26 is arranged on the innermost periphery of the upper surface 21 of the wall 20, so that stress concentration on the adhesive 50 in a case where the imaging device 1 bends may be relieved.

### 3. THIRD EMBODIMENT

The imaging device 1 according to the first embodiment described above uses the protrusion 22 with the apex formed on the outermost periphery of the annular upper surface 21. In contrast, an imaging device 1 according to a third embodiment of the present technology is different from that of the first embodiment described above in using a protrusion with an apex formed in the vicinity of a central portion of an annular upper surface 21.

[Configuration of Cross-section of Imaging Device]

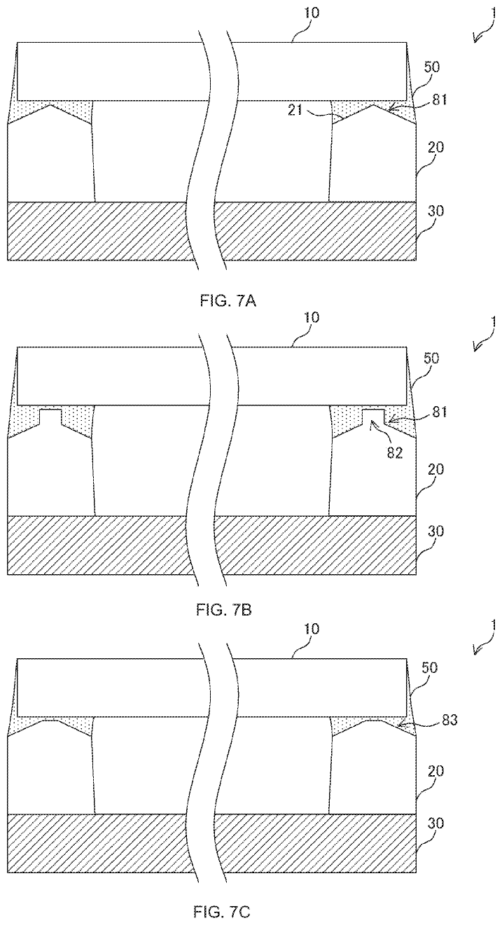

FIG. 7 is a cross-sectional view illustrating a configuration example of the imaging device according to the third embodiment of the present technology. This is a schematic cross-sectional view illustrating a configuration example of the imaging device 1. The imaging device 1 in the drawing is different from the imaging device 1 illustrated in FIG. 2 in that a protrusion 81 is provided in place of the protrusion 22.

In a of the drawing, the protrusion 81 is formed into a slope downward from the apex arranged in a substantial central portion of the annular upper surface 21 toward both outer and inner peripheries. Just as the protrusion 22, the protrusion 81 may be arranged on an entire circumference of the annular upper surface 21. Since the apex of the protrusion 81 is arranged in the central portion of the upper surface 21, a thickness of an adhesive 50 increases from the central portion toward the inner and outer peripheries of the upper surface 21.

In the imaging device 1 in a of the drawing, a stress is applied to the adhesive 50 with the apex of the protrusion 81 as a fulcrum. Since the thickness of the adhesive 50 on the inner periphery and the outer periphery of the upper surface 21 increases, it is possible to relieve the stress applied to the adhesive 50 in a case where a lid 10 bends in the two directions illustrated in FIGS. 3 and 6.

b of the drawing illustrates an example in which a protrusion 82 continuous in a circumferential direction of the upper surface 21 is arranged on the apex of the protrusion 81. Furthermore, c of the drawing illustrates an example of a case where a protrusion 83 in a shape obtained by chamfering an apex is arranged in place of the protrusion 81.

Since the configuration of the imaging device 1 other than this is similar to the configuration of the imaging device 1 described in the first embodiment of the present technology, the description thereof is omitted.

As described above, in the imaging device 1 according to the third embodiment of the present technology, the protrusion 81 is arranged in the substantial central portion of the upper surface 21 of a wall 20, so that stress concentration on the adhesive 50 in a case where the imaging device 1 bends in a different direction may be relieved.

### 4. FOURTH EMBODIMENT

The imaging device 1 according to the first embodiment described above uses the protrusion 22 formed into the downward slope from the apex on the outermost periphery of the annular upper surface 21. In contrast, an imaging device 1 according to a fourth embodiment of the present technology is different from that of the first embodiment described above in forming a step on an annular upper surface 21.

[Configuration of Cross-section of Imaging Device]

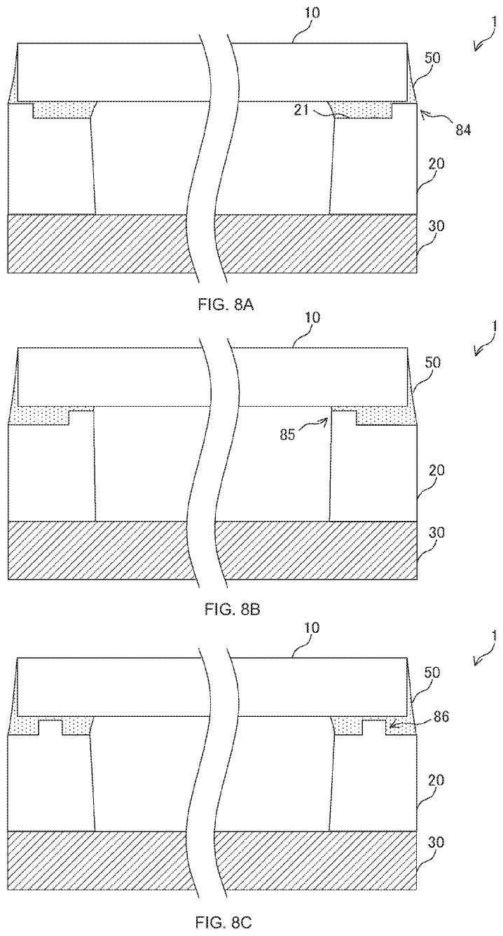

FIG. 8 is a cross-sectional view illustrating a configuration example of the imaging device according to the fourth embodiment of the present technology. This is a schematic cross-sectional view illustrating a configuration example of the imaging device 1. The imaging device 1 in the drawing is different from the imaging device 1 illustrated in FIG. 2 in that a protrusion 84 is provided in place of the protrusion 22.

In a of the drawing, the protrusion 84 is formed into a step shape continuously formed on an outermost periphery of the annular upper surface 21. The upper surface 21 other than the protrusion 84 is formed into a shape parallel to a lid 10. Therefore, an adhesive 50 adjacent to the protrusion 84 becomes thin, and the adhesive 50 adjacent to the upper surface 21 other than the protrusion 84 becomes thick. The thickness of the adhesive 50 on an inner periphery of the upper surface 21 may be increased, so that a stress may be dispersed. Note that, a fulcrum when the stress is applied to the adhesive 50 is formed in the vicinity of the protrusion 84. Furthermore, since the thickness of the adhesive 50 on an outer periphery of the upper surface 21 may be decreased, it is possible to decrease moisture absorption of the imaging device 1. This is because an amount of moisture absorbed into the imaging device 1 increases in proportion to a cross-sectional area of the adhesive 50. In this manner, the imaging device 1 in a of the drawing may prevent damage by an influence of heat at the time of manufacture and the like and decrease the moisture absorption during use.

b of the drawing illustrates an example in which a stepped protrusion 85 continuously formed on an innermost periphery of the annular upper surface 21 is arranged. Furthermore, c of the drawing illustrates an example in which a stepped protrusion 86 formed continuously in a substantial central portion of the annular upper surface 21 is arranged.

The protrusion 84 may be formed by using a spacer, for example. At that time, by using the spacer formed by using the same material as that of the adhesive 50, stress concentration on the adhesive 50 may be relieved.

Since the configuration of the imaging device 1 other than this is similar to the configuration of the imaging device 1 described in the first embodiment of the present technology, the description thereof is omitted.

As described above, in the imaging device 1 according to the fourth embodiment of the present technology, by arranging the stepped protrusion 81 on the upper surface 21 of the wall 20, it is possible to relieve the stress concentration based on a change in temperature at the time of manufacture and during use of the imaging device 1. Therefore, damage of the imaging device 1 may be prevented.

### 5. APPLICATION EXAMPLE TO CAMERA

The present technology may be applied to various products. For example, the present technology may be realized as an imaging element mounted on an imaging device such as a camera.

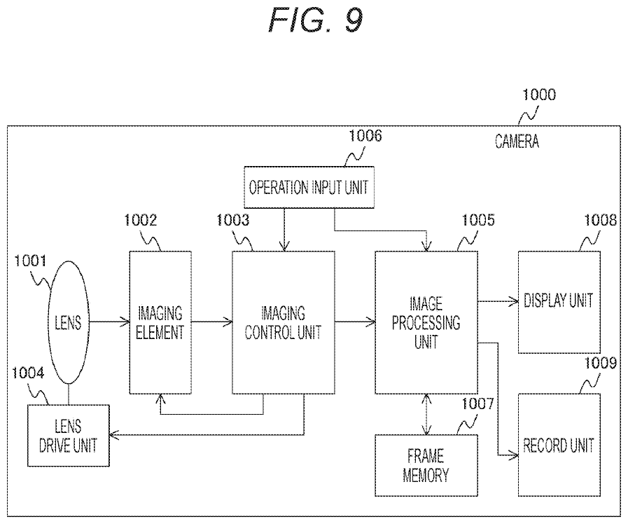

FIG. 9 is a block diagram illustrating a schematic configuration example of a camera which is an example of an imaging device to which the present technology may be applied. A camera 1000 in the drawing is provided with a lens 1001, an imaging element 1002, an imaging control unit 1003, a lens drive unit 1004, an image processing unit 1005, an operation input unit 1006, a frame memory 1007, a display unit 1008, and a record unit 1009.

The lens 1001 is an imaging lens of the camera 1000. The lens 1001 condenses light from a subject and allows the same to be incident on the imaging element 1002 to be described later to form an image of the subject.

The imaging element 1002 is a semiconductor element which images the light from the subject condensed by the lens 1001. The imaging element 1002 generates an analog image signal corresponding to the applied light and converts the same into a digital image signal to output.

The imaging control unit 1003 controls imaging by the imaging element 1002. The imaging control unit 1003 controls the imaging element 1002 by generating a control signal and outputting the same to the imaging element 1002. Furthermore, the imaging control unit 1003 may perform autofocus in the camera 1000 on the basis of the image signal output from the imaging element 1002. Here, the autofocus is a system which detects a focal position of the lens 1001 to automatically adjust. As the autofocus, a method of detecting the focal position by detecting an image plane phase difference by a phase difference pixel arranged in the imaging element 1002 (image plane phase difference autofocus) may be used. Furthermore, a method of detecting a position where contrast of an image is the highest as the focal position (contrast autofocus) may also be applied. The imaging control unit 1003 adjusts a position of the lens 1001 via the lens drive unit 1004 on the basis of the detected focal position and perform autofocus. Note that, the imaging control unit 1003 may be formed by using, for example, a digital signal processor (DSP) equipped with firmware.

The lens drive unit 1004 drives the lens 1001 on the basis of control of the imaging control unit 1003. The lens drive unit 1004 may drive the lens 1001 by changing the position of the lens 1001 using a built-in motor.

The image processing unit 1005 processes the image signal generated by the imaging element 1002. This processing includes, for example, demosaicing of generating an image signal of a lacking color among the image signals corresponding to red, green, and blue for each pixel, noise reduction of removing noise of the image signal, encoding of the image signal and the like. The image processing unit 1005 may be formed by using, for example, a microcomputer equipped with firmware.

The operation input unit 1006 receives an operation input from a user of the camera 1000. As the operation input unit 1006, for example, a push button or a touch panel may be used. The operation input received by the operation input unit 1006 is transmitted to the imaging control unit 1003 and the image processing unit 1005. Thereafter, processing according to the operation input, for example, processing such as imaging of a subject is started.

The frame memory 1007 is a memory which stores a frame which is the image signal for one screen. The frame memory 1007 is controlled by the image processing unit 1005 and holds the frame in the course of the image processing.

The display unit 1008 displays an image processed by the image processing unit 1005. As the display unit 1008, for example, a liquid crystal panel may be used.

The record unit 1009 records the image processed by the image processing unit 1005. As the record unit 1009, for example, a memory card or a hard disk may be used.

The camera to which the present invention may be applied is described above. The present technology may be applied to the imaging element 1002 among the configurations described above. Specifically, the imaging device 1 illustrated in FIG. 1 may be applied to the imaging element 1002. By applying the imaging device 1 to the imaging element 1002, it is possible to prevent damage of the imaging device 1 in accordance with a change in temperature during use.

Note that, the camera is herein described as an example, but the technology according to the present invention may be applied to, for example, a monitoring device and the like in addition to this.

Note that, the configuration of the semiconductor device according to the embodiment of the present technology is not limited to the example of the imaging device. For example, this may be applied to a semiconductor device using a hollow package, such as a sensor or a flat type display device, for example.

Lastly, the description of each of the above-described embodiments is an example of the present technology, and the present technology is not limited to the above-described embodiments. For this reason, it goes without saying that, in addition to the embodiments described above, various changes may be made according to a design and the like without departing from the technical idea according to the present technology.

Note that, the present technology may also have a following configuration.

(1) A semiconductor device provided with:

a frame including a bottom and a wall arranged so as to be adjacent to the bottom and formed into an annular shape, the wall provided with a protrusion continuous in a circumferential direction of the annular shape on an upper surface;

a semiconductor chip placed on the bottom surrounded by the wall; and

a lid adhered to the frame at the upper surface.

(2) The semiconductor device according to (1) described above,

in which the frame is provided with the protrusion formed into a slope downward from an apex.

(3) The semiconductor device according to (2) described above,

in which the frame is provided with the protrusion including the apex formed on an outer periphery of the upper surface.

(4) The semiconductor device according to (2) described above,

in which the frame is provided with the protrusion including the apex formed on an inner periphery of the upper surface.

(5) The semiconductor device according to (2) described above,

in which the frame is provided with the protrusion including the apex formed in a central portion of the upper surface.

(6) The semiconductor device according to (1) described above,

in which the frame is provided with the protrusion including a step formed on the upper surface.

(7) The semiconductor device according to any one of (1) to (6) described above, further provided with

an adhesive arranged between the upper surface and the lid to be cured while being pressurized.

(8) An imaging device provided with:

a frame including a bottom and a wall arranged so as to be adjacent to the bottom and formed into an annular shape, the wall provided with a protrusion continuous in a circumferential direction of the annular shape on an upper surface;

an imaging element placed on the bottom surrounded by the wall; and

a lid adhered to the frame at the upper surface and transmits light incident on the imaging element.

(9) A manufacturing method of a semiconductor device provided with:

an adhesive arranging step of arranging an adhesive by applying the adhesive to an upper surface of a frame including a bottom and a wall arranged so as to be adjacent to the bottom and formed into an annular shape, the wall provided with a protrusion continuous in a circumferential direction of the annular shape on an upper surface;

a lid placing step of placing a lid on the upper surface of the frame on which the adhesive is arranged; and

an adhering step of adhering the frame and the lid by curing while pressurizing the arranged adhesive.

### REFERENCE SIGNS LIST

1 Imaging device

10 Lid

20 Wall

21 Upper surface

22, 24 to 27, 81 to 86 Protrusion

23 Bump

30 Bottom

40 Imaging element

50 Adhesive

1002 Imaging element

1. A semiconductor device comprising:
a frame including a bottom and a wall arranged so as to be adjacent to the bottom and formed into an annular shape, the wall provided with a protrusion continuous in a circumferential direction of the annular shape on an upper surface;
a semiconductor chip placed on the bottom surrounded by the wall; and
a lid adhered to the frame at the upper surface.

2. The semiconductor device according to claim 1,
wherein the frame is provided with the protrusion formed into a slope downward from an apex.

3. The semiconductor device according to claim 2,
wherein the frame is provided with the protrusion including the apex formed on an outer periphery of the upper surface.

4. The semiconductor device according to claim 2,
wherein the frame is provided with the protrusion including the apex formed on an inner periphery of the upper surface.

5. The semiconductor device according to claim 2,
wherein the frame is provided with the protrusion including the apex formed in a central portion of the upper surface.

6. The semiconductor device according to claim 1,
wherein the frame is provided with the protrusion including a step formed on the upper surface.

7. The semiconductor device according to claim 1, further comprising
an adhesive arranged between the upper surface and the lid to be cured while being pressurized.

8. An imaging device comprising:
a frame including a bottom and a wall arranged so as to be adjacent to the bottom and formed into an annular shape, the wall provided with a protrusion continuous in a circumferential direction of the annular shape on an upper surface;
an imaging element placed on the bottom surrounded by the wall; and
a lid adhered to the frame at the upper surface and transmits light incident on the imaging element.

9. A manufacturing method of a semiconductor device comprising:
an adhesive arranging step of arranging an adhesive by applying the adhesive to an upper surface of a frame including a bottom and a wall arranged so as to be adjacent to the bottom and formed into an annular shape, the wall provided with a protrusion continuous in a circumferential direction of the annular shape on an upper surface;
a lid placing step of placing a lid on the upper surface of the frame on which the adhesive is arranged; and
an adhering step of adhering the frame and the lid by curing while pressurizing the arranged adhesive.
